(19) United States
(12) Patent Application Publication
(10) Pub. No.: US 2025/0255157 A1
(43) Pub. Date: Aug. 7, 2025

(54) DISPLAY DEVICE AND METHOD OF MANUFACTURING THE SAME

(71) Applicant: Samsung Display Co., LTD., Yongin-si (KR)

(72) Inventors: Soo Dong KIM, Yongin-si (KR); Jung Hwan YI, Yongin-si (KR); Rae Young KIM, Yongin-si (KR); Jang Il KIM, Yongin-si (KR); Su Jin LEE, Yongin-si (KR); Si Wan JEON, Yongin-si (KR)

(21) Appl. No.: 18/793,297

(22) Filed: Aug. 2, 2024

(30) Foreign Application Priority Data
Feb. 5, 2024 (KR) 10-2024-0017560

(51) Int. Cl. H10K 59/80; H10K 59/38

(52) U.S. Cl. CPC H10K 59/879; H10K 59/38

(57) ABSTRACT

A display device includes: a light emitting element layer, an optical functional layer including optical functional patterns arranged on the light emitting element layer and a bank disposed between the optical functional patterns, a color filter layer which is disposed on the optical functional layer and includes color filters overlapping the optical functional patterns in a plan view, and a lens array disposed between the optical functional layer and the color filter layer. The lens array includes: partition walls arranged on a bottom surface of the color filter layer, which are adjacent to the optical functional layer, and a low refractive layer covering the partition walls and the bottom surface of the color filter layer.

This application claims priority to Korean patent application No. 10-2024-0017560, filed on Feb. 5, 2024, and all the benefits accruing therefrom under 35 U.S.C. § 119, the content of which in its entirety is herein incorporated by reference.

### BACKGROUND

### 1. Technical Field

The present disclosure generally relates to a display device and a method of manufacturing the same.

### 2. Related Art

With the development of multimedia, the importance of display devices has increased. Accordingly, various types of display devices such as an Organic Light Emitting Display (OLED) and a Liquid Crystal Display (LCD) are used.

A display device includes a display panel as a device for displaying an image, such as an organic light emitting display panel (OLED panel) or a liquid crystal display panel (LCD panel). The OLED panel may allow light generated in a light emitting layer to be emitted not only in a front direction but also in a side direction. Light efficiency may be determined with respect to light emitted in the front direction. In other words, as used herein, the “light efficiency” may be defined as a ratio of amount of light emitted in the front direction to total amount of emitted light. That is, light emitted in the side direction may cause deterioration of the light efficiency. Accordingly, it is desirable to increase light emitted in the front direction in the display device, thereby improving the light efficiency.

The above information disclosed in this Related Art section is only for enhancement of understanding of the background of the disclosure and therefore it may contain information that does not form the prior art that is already known in this country to a person of ordinary skill in the art.

### SUMMARY

Embodiments also provide a method of manufacturing a display device having improved light efficiency.

In accordance with an aspect of the present disclosure, there is provided a display device including: a light emitting element layer; an optical functional layer including optical functional patterns arranged on the light emitting element layer and a bank disposed between the optical functional patterns; a color filter layer disposed on the optical functional layer, the color filter layer including color filters overlapping the optical functional patterns in a plan view; and a lens array disposed between the optical functional layer and the color filter layer, wherein the lens array includes: partition walls arranged on a bottom surface of the color filter layer, which are adjacent to the optical functional layer; and a low refractive layer covering the partition walls and the bottom surface of the color filter layer.

The partition walls may have a refractive index higher than a refractive index of the low refractive layer.

The partition walls may have a light transmittance of 95% or more.

The low refractive layer may have a refractive index of 1 to 1.5.

Each of the optical functional patterns may overlap with at least one of the partition walls in the plan view.

A bottom surface of the low refractive layer, which is adjacent to the optical functional layer, may include concave portions recessed toward the bottom surface of the color filter layer.

Each of the optical functional patterns may overlap with at least two of the concave portions in the plan view.

The lens array may further include lenses disposed between the optical functional layer and the low refractive layer.

Each of the lenses may have a refractive index higher than the refractive index of the low refractive layer.

Each of the lenses may have a shape complementary to a shape of a portion of the low refractive layer facing the lens.

Each of the lenses may have a first thickness at the partition walls and a second thickness at the bottom surface of the color filter layer between the partition walls. The first thickness may be thinner than the second thickness.

The color filters may include a first color filter and a second color filter, which are arranged in a certain direction. The partition walls may include: an external partition wall overlapping the bank; and at least one internal partition wall overlapping with each of the first and second color filters in the plan view.

The external partition wall may be disposed along an edge of each of the first and second color filters in the plan view.

The external partition wall may include a light absorbing material.

A thickness of the low refractive layer may increase in a direction toward the partition walls.

One of the partition walls may have a top surface adjacent to the color filter layer, a bottom surface opposite to the top surface, and first and second side surfaces connecting the top surface and the bottom surface to each other. The low refractive layer may be in contact with the first side surface, the second side surface, and the bottom surface, and surround part of the partition walls.

In accordance with another aspect of the present disclosure, there is provided a display device including: a light emitting element layer; an optical functional layer including optical functional patterns arranged on the light emitting element layer and a bank disposed between the optical functional patterns; a color filter layer disposed on the optical functional layer, the color filter layer including color filters overlapping with the optical functional patterns in a plan view; and a lens array disposed between the optical functional layer and the color filter layer, wherein the lens array includes: lenses disposed on the optical functional layer, the lenses having at least two convex shapes overlapping with each of the optical functional patterns in the plan view; and a low refractive layer covering the lenses and a bottom surface of the color filter layer, which is adjacent to the optical functional layer.

The low refractive layer may have a property that a low temperature process of 100 degrees or lower is possible.

In accordance with still another aspect of the present disclosure, there is provided a method of manufacturing a display device, the method including: forming a light emitting element layer on a first substrate; forming, on the light emitting element layer, an optical functional layer including optical functional patterns and a bank disposed between the optical functional patterns; forming, on a second substrate, a color filter layer including color filters overlapping with the optical functional patterns; forming partition walls on the color filter layer; forming a low refractive layer covering the partition walls and the color filter layer; and bonding the first substrate and the second substrate to each other with a filler member interposed therebetween.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating an embodiment of a display device of the present disclosure.

FIG. 2 is a block diagram illustrating an embodiment of any one of sub-pixels shown in FIG. 1.

FIG. 3 is a plan view illustrating an embodiment of a display panel shown in FIG. 1.

FIG. 4 is a sectional view illustrating an embodiment of the display panel shown in FIG. 1.

FIG. 5 is a plan view illustrating an embodiment of any one of pixels shown in FIG. 3.

FIG. 6 is a sectional view taken along line I-I′ shown in FIG. 5.

FIG. 7 is a sectional view illustrating portion A shown in FIG. 6.

FIG. 8 is a plan view illustrating an embodiment of partition walls disposed in the one of the pixels shown in FIG. 3.

FIG. 9 is a plan view illustrating a pixel in accordance with another embodiment of the present disclosure.

FIG. 10 is a flowchart illustrating an embodiment of a method of manufacturing the display device shown in FIG. 6.

FIG. 11 is a sectional view of the display device in S1020 shown in FIG. 10.

FIG. 12 is a sectional view of the display device in S1040 shown in FIG. 10.

FIG. 13 is a flow chart illustrating an embodiment of S1030 shown in FIG. 10.

FIG. 14 is a sectional view of the display device in S1032 shown in FIG. 13.

FIG. 15 is a sectional view of the display device in S1033 shown in FIG. 13.

FIG. 16 is a sectional view illustrating another embodiment of the display device.

### DETAILED DESCRIPTION

Hereinafter, embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

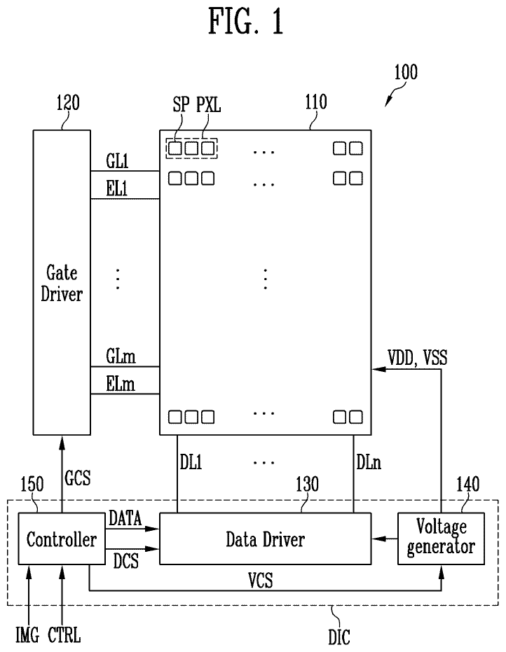

FIG. 1 is a block diagram illustrating an embodiment of a display device of the present disclosure.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

Each of the sub-pixels SP may include at least one light emitting element configured to generate light. Accordingly, each of the sub-pixels SP may generate light of a specific color such as red, green, blue, cyan, magenta or yellow. Two or more sub-pixels among the sub-pixels SP may constitute one pixel PXL. For example, three sub-pixels SP may constitute one pixel PXL as shown in FIG. 1.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In embodiments, the gate control signal GCS may include a start signal indicating a start of each frame, a horizontal synchronization signal for outputting gate signals in synchronization with timings at which data signals are applied, and the like.

In embodiments, first to mth light emitting control lines EL1 to ELm connected to the sub-pixels SP in the row direction may be further provided. The gate driver 120 may include an emission control driver configured to control the first to mth emission control lines EL1 to ELm, and the emission control driver may operate under the control of the controller 150.

The gate driver 120 may be disposed at one side of the display panel 110. However, embodiments are not limited thereto. For another example, the gate driver 120 may be divided into two or more drivers which are physically and/or logically divided, and these drivers may be disposed at one side of the display panel 110 and the other side of the display panel 110, which is opposite to the one side. As such, in some embodiments, the gate driver 120 may be disposed in various forms at the periphery of the display panel 110.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the data line DL1 to DLm. Accordingly, corresponding sub-pixels SP may generate light corresponding to the data signals. Accordingly, an image may be displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. In other embodiments, the first power voltage VDD or the second power voltage VSS may be provided by an external device of the display device 100.

Besides, the voltage generator 140 may generate various voltages. For example, the voltage generator 140 may generate an initialization voltage applied to the sub-pixels SP. For example, a predetermined reference voltage may be applied to the first to nth data lines DL1 to DLn in a sensing operation for sensing electrical characteristics of transistors and/or light emitting elements of the sub-pixels SP, and the voltage generator 140 may generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. In embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from the driver integrated circuit DIC.

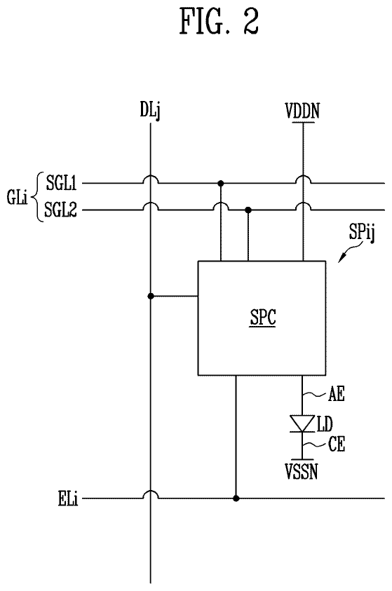

FIG. 2 is a block diagram illustrating an embodiment of any one of the sub-pixels shown in FIG. 1. In FIG. 2, a sub-pixel SPij arranged on an ith row (i is an integer which is greater than or equal to 1 and is smaller than or equal to m) and a jth column (j is an integer which is greater than or equal to 1 and is smaller than or equal to n) among the sub-pixels SP shown in FIG. 1 is exemplarily illustrated.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an ith gate line GLi among the first to mth gate lines GL1 to GLm shown in FIG. 1, an ith emission control line ELi among the first to mth emission control lines EL1 to ELm shown in FIG. 1, and a jth data line DLj among the first to nth data lines DL1 to DLn shown in FIG. 1. The sub-pixel circuit SPC may be configured to control the light emitting element LD according to signals received through these signal lines.

The sub-pixel circuit SPC may operate in response to a gate signal received through the ith gate line GLi. The ith gate line GLi may include one or more sub-gate lines. In embodiments, as shown in FIG. 2, the ith gate line GLi may include first and second sub-gate lines SGL1 and SGL2. The sub-pixel circuit SPC may operate in response to gate signals received through the first and second sub-gate lines SGL1 and SGL2. As such, when the ith gate line GLi includes two or more sub-gate lines, the sub-pixel circuit SPC may operate in response to gate signals received through the corresponding sub-gate lines.

The sub-pixel circuit SPC may operate in response to an emission control signal received through the ith emission control line ELi. In embodiments, the ith emission control line ELi may include one or more sub-emission control lines. When the ith emission control line ELi includes two or more sub-emission control lines, the sub-pixel circuit SPC may operate in response to emission control signals received through the corresponding emission control lines.

The sub-pixel circuit SPC may receive a data signal through the jth data line DLj. The sub-pixel circuit SPC may store a voltage corresponding to the data signal in response to at least one of the gate signals received through the first and second sub-gate lines SGL1 and SGL2. The sub-pixel circuit SPC may control a current flowing from the first power voltage node VDDN to the second power voltage node VSSN through the light emitting element LD according to the stored voltage in response to the emission control signal received through the ith emission control line ELi. Accordingly, the light emitting element LD may generate light with a luminance corresponding to the data signal.

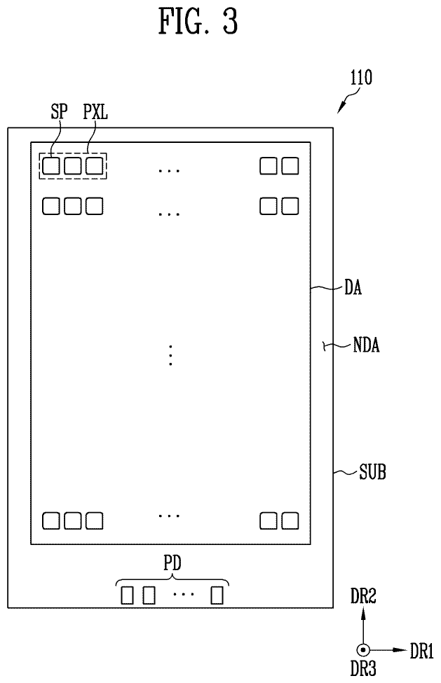

FIG. 3 is a plan view illustrating an embodiment of the display panel shown in FIG. 1. As used herein, the “plan view” is a view in a thickness direction (i.e., third direction DR3) of a substrate SUB.

Referring to FIG. 3, the display panel 110 shown in FIG. 1 may include a display area DA and a non-display area NDA. The display panel 110 may display an image through the display area DA. The non-display area NDA may be disposed at the periphery of the display area DA.

The display panel 110 may include a substrate SUB, sub-pixels SP, and pads PD.

The sub-pixels SP may be disposed in the display area DA on the substrate SUB. The sub-pixels SP may be arranged in a matrix form along a first direction DR1 and a second direction DR2 intersecting the first direction DR1. However, embodiments are not limited thereto. For another example, the sub-pixels SP may be arranged in a zigzag form along the first direction DR1 and the second direction DR2. For example, the sub-pixels SP may be disposed in a PENTILE™ form. The first direction DR1 may be a row direction, and the second direction DR2 may be a column direction.

Two or more sub-pixels among the sub-pixels SP may constitute one pixel PXL.

A component for controlling the sub-pixels SP may be disposed in the non-display area NDA on the substrate SUB. For example, lines connected to the sub-pixels SP, such as the first to mth gate lines GL1 to GLm and the first to nth data lines DL1 to DLn, which are shown in FIG. 1, may be disposed in the non-display area NDA.

At least one of the gate driver 120, the data driver 130, the voltage generator 140, and the controller 150, which are shown in FIG. 1, may be integrated in the non-display area NDA of the display panel 110. In embodiments, the gate driver 120 shown in FIG. 1 is mounted on the display panel 110, and may be disposed in the non-display area NDA. In other embodiments, the gate driver 120 may be implemented as an integrated circuit distinguished from the display panel 110.

The pads PD may be disposed in the non-display area NDA on the substrate SUB. The pads PD may be electrically connected to the sub-pixels SP through the lines. For example, the pads PD may be connected to the sub-pixels SP through the first to nth data lines DL1 to DLn.

The pads PD may interface the display panel 110 with other components of the display device 100 (see FIG. 1). In embodiments, voltages and signals, which are for operations of components included in the display panel 110, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel 110, the gate control signal GCS may be transmitted from the driver integrated circuit DIC to the gate driver 120 through the pads PD.

In embodiments, a circuit board may be electrically connected to the pads PD, using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

In embodiments, the display area DA may have various shapes. The display area DA may have a closed-loop shape including linear sides and/or curved sides. For example, the display area DA may have shapes such as a polygon, a circle, a semicircle, and an ellipse.

In embodiments, the display panel 110 may have a flat display surface. In other embodiments, the display panel 110 may at least partially have a round display surface. In embodiments, the display panel 110 may be bendable, foldable or rollable. The display panel 110 and/or the substrate SUB may include materials having flexibility.

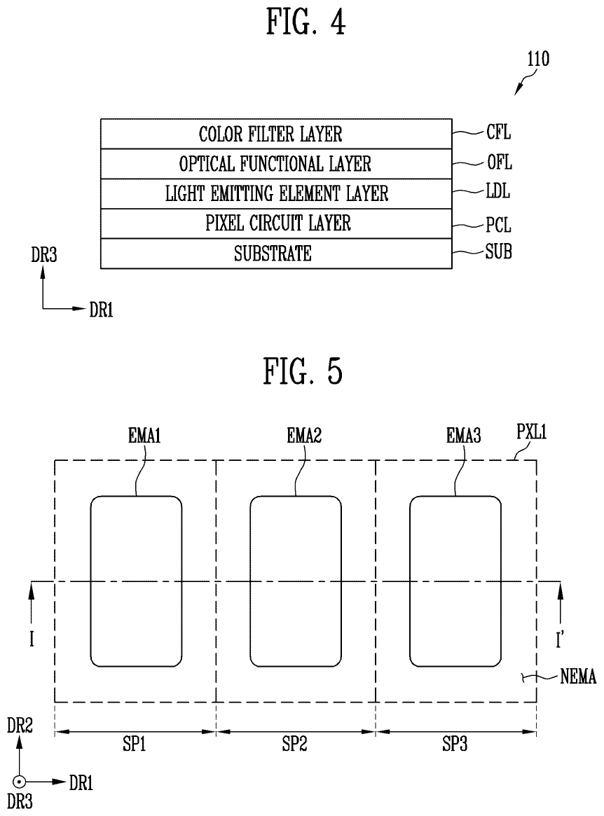

FIG. 4 is a sectional view illustrating an embodiment of the display panel shown in FIG. 1.

Referring to FIG. 4, the display panel 110 may include a substrate SUB, a pixel circuit layer PCL, a light emitting element layer LDL, an optical functional layer OFL, and a color filter layer CFL.

The pixel circuit layer PCL may be disposed on the substrate SUB. The pixel circuit layer PCL may include circuit elements of a pixel circuit (see FIG. 2) and at least one insulating layer located between the circuit elements. The circuit elements may include a plurality of transistors and signal lines connected to the transistors. In an example, each of the transistors may be a Metal Oxide Semiconductor Field Effect Transistor (MOSFET), but the present disclosure is not limited thereto. Also, each of the transistors may have a form in which a semiconductor layer, a gate electrode, and source/drain electrodes are sequentially stacked with the insulating layer interposed therebetween.

The substrate SUB and the pixel circuit layer PCL, which are described above, may be formed by applying a semiconductor process and equipment, but the present disclosure is not limited thereto.

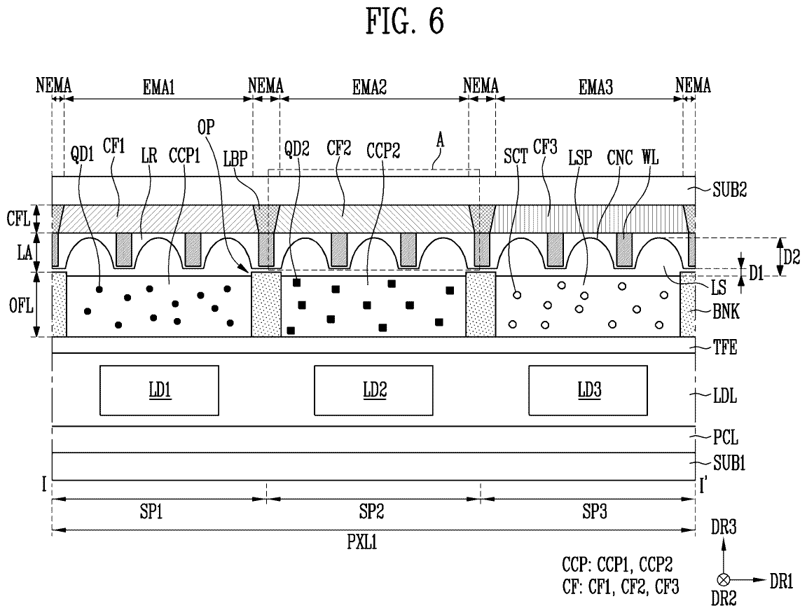

The light emitting element layer LDL may include light emitting elements LD (see FIG. 6) emitting light. The light emitting elements LD may be disposed in first to third sub-pixels SP1 to SP3, respectively. In an embodiment, the light emitting elements LD may emit light of the same color. Due to color filters CF of different colors, which are disposed on the respective light emitting elements LD, the first to third sub-pixels SP1 to SP3 may emit lights of different colors. In another embodiment, the light emitting elements LD may emit light of different colors. However, the color, kind, and the like of the light emitting elements LD of the light emitting element layer LDL are not limited.

The optical functional layer OFL may be disposed on the light emitting element layer LDL. The optical functional layer OFL may change a wavelength (or color) of light emitted from the light emitting element layer LDL, using a quantum dot. The optical functional layer OFL may be formed on a base surface provided by the light emitting element layer LDL through a continuous process.

However, it is described that the optical functional layer OFL is provided separately from the light emitting element layer LDL. However, the present disclosure is not limited thereto. For another example, the light emitting element provided in the light emitting element layer LDL may be implemented as a light emitting element (quantum dot display element) emitting light by changing a wavelength of emitted light, using a quantum dot.

The color filter layer CFL may be disposed on the optical functional layer OFL. The color filter layer CFL may allow light emitted from each light emitting element LD to be selectively transmitted in an image display direction (or front direction) of the display device 100 therethrough. However, the present disclosure is not limited thereto.

The color filter layer CFL may include color filters which allow light of one color to be selectively transmitted therethrough. That is, the color filter layer CFL may allow light emitted from the light emitting elements LD to be selectively transmitted in an image display direction (or front direction) of the display panel 110 therethrough.

Although not shown in FIG. 4, a lens array LA (see FIG. 6) may be disposed between the light function layer OFL and the color filter layer CFL. The lens array LA may include at least two lenses with respect to each sub-pixel SP. The lens array LA may function to improve the extraction efficiency of light (i.e., light efficiency) emitted from the light emitting elements LD.

FIG. 5 is a plan view illustrating an embodiment of any one of the pixels shown in FIG. 3. In FIG. 5, for clear and brief description, any one of the pixels PXL shown in FIG. 3 is schematically illustrated as a first pixel PXL1. The other pixels may be configured identically to the first pixel PXL1.

Referring to FIG. 5, the first pixel PXL1 may include first to third sub-pixels SP1 to SP3 arranged in the first direction DR1.

The first sub-pixel SP1 may include a first emission area EMA1 and a non-emission area NEMA at the periphery of the first emission area EMA1. The second sub-pixel SP2 may include a second emission area EMA2 and the non-emission area NEMA at the periphery of the second emission area EMA2. The third sub-pixel SP3 may include a third emission area EMA3 and the non-emission area NEMA at the periphery of the third emission area EMA3.

The first emission area EMA1 may be an area in which light is emitted through an optical functional pattern corresponding to the first sub-pixel SP1. The second emission area EMA2 may be an area in which light is emitted through an optical functional pattern corresponding to the second sub-pixel SP2. The third emission area EMA3 may be an area in which light is emitted through an optical functional pattern corresponding to the third sub-pixel SP3. As described with reference to FIG. 5, each emission area may be understood as an area overlapping with an optical functional pattern corresponding to the first to third sub-pixels SP1 to SP3.

FIG. 6 is a sectional view taken along line I-I′ shown in FIG. 5.

Referring to FIG. 6, the first pixel PXL1 may include a first substrate SUB1, a pixel circuit layer PCL, a light emitting element layer LDL, a thin film encapsulation layer TFE, an optical functional layer OFL, a lens array LA, a color filter layer CFL, and a second substrate SUB2.

The light emitting element layer LDL including first to third light emitting elements LD1 to LD3 may be disposed on the first substrate SUB1. In addition, the pixel circuit layer PCL may be disposed between the first substrate SUB1 and the light emitting element layer LDL.

The pixel circuit layer PCL may include various driving elements for driving the first to third light emitting elements LD1 to LD3, lines, and the like. For example, the pixel circuit layer PCL may include transistors and storage capacitors, which are included in a sub-pixel circuit SPC (see FIG. 2) of each of first to third sub-pixels SP1 to SP3. For example, the pixel circuit layer PCL may further include lines such as a scan line and a data line, which are connected to first to third sub-pixels SP1 to SP3 of each pixel. Besides, the pixel circuit layer PCL may include various components, but embodiments are not limited thereto.

The light emitting element layer LDL may include the first light emitting element LD1 located in the first sub-pixel SP1, the second light emitting element LD2 located in the second sub-pixel SP2, and the third light emitting element LD3 located in the third sub-pixel SP3. In some embodiments, each of the first to third light emitting elements LD1 to LD3 may include a self-emissive element such as an organic light emitting diode. For example, each of the first to third light emitting elements LD1 to LD3 may have a form in which an anode electrode AE (see FIG. 2), a hole transport layer, an organic light emitting layer, an electron transport layer, and a cathode electrode CE (see FIG. 2) are sequentially stacked, but the present disclosure is not limited thereto. For another example, each of the first to third light emitting elements LD1 to LD3 may include an inorganic light emitting element including an inorganic light emitting material.

In some embodiments, the anode electrode AE may be formed by being patterned for each of the first to third sub-pixels SP1 to SP3. Since the anode electrode AE supplies holes to the organic light emitting layer, the anode electrode AE may be made of a transparent conductive material having a high work function. For example, the anode electrode AE may be made of a transparent conductive material such as tin oxide (TO), zinc oxide (ZnO), indium tin oxide (ITO), indium zinc oxide (IZO), or indium tin zinc oxide (ITZO), but the present disclosure is not limited thereto.

The organic light emitting layer may be disposed between the anode electrode AE and the cathode electrode CE. The organic light emitting layer may emit light as electrons and holes, which are supplied from the anode electrode AE and the cathode electrode CE, are combined therein.

The cathode electrode CE may be disposed on the organic light emitting layer. The cathode electrode CE may be formed as one layer throughout a front surface of the first substrate SUB1. Cathode electrodes CE of the first to third sub-pixels SP1 to SP3 may be connected to each other to be integrally formed. Since the cathode electrode CE supplies electrons to the organic light emitting layer, the cathode electrode CE may include a conductive material having a low work function. For example, the cathode electrode CE may be made of a transparent conductive material such as tin oxide (TO), zinc oxide (ZnO), indium tin oxide (ITO), indium zinc oxide (IZO), or indium tin zinc oxide (ITZO), or an ytterbium alloy. Also, the cathode electrode CE may be made of a metal material such as silver (Ag), copper (Cu), or a magnesium-silver (Mg—Ag) alloy, or a metal material having a very thin thickness, but the present disclosure is not limited thereto.

The thin film encapsulation layer TFE may be disposed on the light emitting element layer LDL. The thin film encapsulation layer TFE may be an encapsulation substrate or have the form of an encapsulation layer provided as a multi-layer. When the thin film encapsulation layer TFE has the form of the encapsulation layer, the thin film encapsulation layer TFE may include an inorganic layer and/or an organic layer. For example, the thin film encapsulation layer TFE may have a form in which an inorganic layer, an organic layer, and an inorganic layer are sequentially stacked. The thin film encapsulation layer TFE may prevent external air and moisture from infiltrating into the light emitting element layer LDL and the pixel circuit layer PCL. However, the thin film encapsulation layer TFE may be omitted in another embodiment.

The optical functional layer OFL may be disposed on the thin film encapsulation layer TFE. The optical functional layer OFL may include optical functional patterns CCP and banks BNK disposed between the optical functional patterns CCP. Also, the optical functional layer OFL may further include a light scattering pattern LSP including a scatterer SCT.

The banks BNK may be disposed on the thin film encapsulation layer TFE. The banks BNK may be in contact with the thin film encapsulation layer TFE. The banks BNK may protrude in a thickness direction of the first substrate SUB1 (e.g., a third direction DR3) from the thin film encapsulation layer TFE.

Also, the banks BNK may include at least one of an organic material, an inorganic material, and a metal. In an example, the bank BNK may include various inorganic materials including silicon nitride (SiNₓ), silicon oxide (SiOₓ), or the like. Alternatively, the banks BNK may include various kinds of organic materials or include a combination of an organic material and an inorganic material. For example, the banks BNK may include niobium oxide (Nb₂O₅), silicon nitride (SiNₓ), tantalum pentoxide (Ta₂O₅), zirconium dioxide (ZrO₂), titanium dioxide (TiO₂), aluminum (Al), titanium (Ti), silver (Ag), and the like. However, the present disclosure is not limited thereto. That is, the material constituting the banks BNK may be variously changed.

In embodiments, the banks BNK may define first to third emission areas EMA1 to EMA3. The banks BNK may define openings OP therebetween. For example, the openings OP may be formed by etching the banks BNK. In addition, the optical functional patterns CCP and the light scattering pattern LSP may be disposed in the openings OP. For example, by using an inkjet printing technique, a first optical functional pattern CCP1 may be supplied and formed in the first emission area EMA1, a second optical functional pattern CCP2 may be supplied and formed in the second emission area EMA2, and the light scattering pattern LSP may be supplied and formed in the third emission area EMA3.

As such, the first and second optical functional patterns CCP1 and CCP2 and the light scattering pattern LSP, which accord with colors, may be disposed in the openings OP overlapping with the first to third emission areas EMA1 to EMA3, respectively.

The first and second optical functional patterns CCP1 and CCP2 and the light scattering pattern LSP may be disposed on the light emitting element layer LDL. The first and second optical functional patterns CCP1 and CCP2 and the light scattering pattern LSP may be disposed downwardly of color filters CF. The first and second optical functional patterns CCP1 and CCP2 and the light scattering pattern LSP may be disposed downwardly of the lens array LA. That is, the first and second optical functional patterns CCP1 and CCP2 and the light scattering pattern LSP may be disposed between the light emitting element layer LDL and the lens array LA. Also, the first and second optical functional patterns CCP1 and CCP2 and the light scattering pattern LSP may be disposed (or patterned) while being surrounded by the banks BNK.

The first and second optical functional patterns CCP1 and CCP2 may be configured to change a wavelength of light. The first and second optical functional patterns CCP1 and CCP2 may include quantum dots QD. In embodiments, the first to third light emitting elements LD1 to LD3 may be configured to blue light. The first optical functional pattern CCP1 may include first light conversion particles which convert light of a third color (e.g., blue), which is emitted from a blue light emitting layer of the first light emitting element LD1, into light of a first color (e.g., red). For example, the first optical functional pattern CCP1 may include a plurality of first quantum dots QD1 dispersed in a matrix material such as base resin. The first quantum dot QD1 may absorb blue light and emit red light by shifting a wavelength of the blue light according to energy transition.

The second optical functional pattern CCP2 may include second light conversion particles which convert light of a third color (e.g., blue), which is emitted from a blue light emitting layer of the second light emitting element LD2, into light of a second color (e.g., green). For example, the second optical functional pattern CCP1 may include a plurality of second quantum dots QD2 dispersed in a matrix material such as base resin. The second quantum dot QD2 may absorb blue light and emit green light by shifting a wavelength of the blue light according to energy transition.

As such, light of blue having a relatively short wavelength in a visible light band is incident into each of the first quantum dot QD1 and the second quantum dot QD2, so that absorption coefficients of the first quantum dot QD1 and the second quantum dot QD2 can be increased. Accordingly, the efficiency of light (i.e., light efficiency) emitted from the first pixel PXL1 and a second pixel PXL2 can be improved, and excellent color reproduction can be ensured.

The light scattering pattern LSP may be provided to efficiently output light of a third color (or blue), which is emitted from a blue light emitting layer of the third light emitting element LD3. For example, the light scattering pattern LSP may include the scatterer SCT. In an example, the scatterer SCT of the light scattering pattern LSP may include various light scattering particles or light scattering materials. For example, the scatterer SCT may include at least one of silica (SiOₓ) (e.g., silica bead, hollow silica, or the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the present disclosure is not limited thereto.

The scatterer SCT may be selectively included even inside the first optical functional pattern CCP1 or the second optical functional layer CCP2. Also, the scatterer SCT may be omitted such that the light scattering pattern LSP configured with transparent polymer is provided.

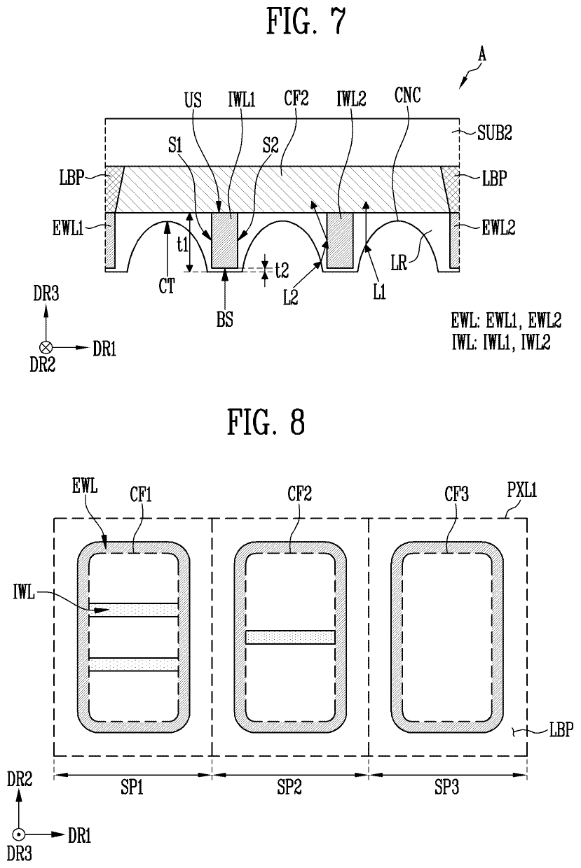

The lens array LA may be disposed on the optical function layer OFL. The lens array LA may be disposed between the optical functional layer OFL and the color filter layer CFL. The lens array LA may condense light emitted from the light emitting element layer LDL to pass through the optical functional layer OFL. For example, the lens array LA may refract light (e.g., light path L1 in FIG. 7) passing through the optical functional layer OFL to generally face in the third direction DR3 (i.e., front direction). The lens array LA may function to improve the extraction efficiency of lights (i.e., light efficiency) emitted from the first to third light emitting elements LD1 to LD3.

The lens array LA may include partition walls WL and a low refractive layer LR. The partition walls WL may be arranged on a bottom surface of the color filter layer CFL, which is adjacent to the optical functional layer OFL. In addition, the low refractive layer LR may cover the partition walls WL and the bottom surface of the color filter layer CFL.

At least one of the partition walls WL may be disposed on each of the openings OP defined between the banks BNK. The partition walls WL may overlap with the first and second optical functional patterns CCP1 and CCP2 and the light scattering pattern LSP in a plan view. In an example, at least one of the partition walls WL may be disposed to overlap with the first optical functional pattern CCP1. At least one of the partition walls WL may be disposed to overlap with the second optical functional pattern CCP2. At least one of the partition walls WL may be disposed to overlap with the light scattering pattern LSP. At least one of the partition walls WL may be disposed to overlap between the first optical functional pattern CCP1 and the second optical functional pattern CCP2 in a plan view. At least one of the partition walls WL may be disposed to overlap between the second optical functional pattern CCP2 and the light scattering pattern LSP.

The low refractive layer LR may be disposed between a first color filter CF1 and the first optical functional pattern CCP1, between a second color filter CF2 and the second optical functional pattern CCP2, and between a third color filter CF3 and the light scattering pattern LSP.

A bottom surface of the low refractive layer LR, which is adjacent to the optical functional layer OFL, may include concave portions CNC recessed toward the bottom surface of the color filter layer CFL (e.g., the third direction DR3). The concave portions CNC may overlap with the first and second optical functional patterns CCP1 and CCP2 and the light scattering pattern LSP in a plan view. In an example, at least two of the concave portions CNC may be disposed to overlap with the first optical functional pattern CCP1. At least two of the concave portions CNC may be disposed to overlap with the second optical functional pattern CCP2. At least two of the concave portions CNC may be disposed to overlap with the light scattering pattern LSP. When an x partition walls WL overlap with each of the first and second optical functional patterns CCP1 and CCP2 and the light scattering pattern LSP, (x+1) concave portions CNC may overlap with each of the first and second optical functional patterns CCP1 and CCP2 and the light scattering pattern LSP (x is an integer greater than or equal to 1) in a plan view.

The low refractive layer LR may be configured to refract or totally reflect light according to an incident angle of the corresponding light. For example, the low refractive layer LR may again provide the first optical functional pattern CCP1 with a portion of light passing through the first optical functional pattern CCP1 so that the portion of light may be provided to the low refractive layer LR again. Accordingly, the low refractive layer LR can improve the light efficiency of the first optical functional pattern CCP1.

In embodiments, the low refractive layer LR may be disposed to partially surround the partition walls WL. The low refractive layer LR may be disposed to other surfaces of the partition walls WL except one surface in contact with the color filter layer CFL. The low refractive layer LR may have a refractive index of 1 to 1.5. In addition, the partition walls WL may have a refractive index higher than the refractive index of the low refractive layer LR, and have a light transmittance of 95% or more. In particular, the partition walls WL may be disposed to be spaced apart from each other in the low refractive layer LR, and have a refractive deviation from the low refractive layer LR. Accordingly, total reflection can effectively occur at side surfaces of the partition walls WL (e.g., light path L2 in FIG. 7).

The lens array LA may further include lenses LS disposed between the optical functional layer OFL and the low refractive layer LR. The lenses LS may be formed by being bonded on the optical functional layer OFL, using the low refractive layer LR surrounding the partition walls WL as a filler member. For example, the lenses LS may be formed by the filler member.

Each of the lenses LS may have a first thickness D1 at the partition walls WL, and have a second thickness D2 at a bottom surface thereof, which is adjacent to the color filter layer CFL. The first thickness D1 may be a thickness of the filler member overlapping with the partition walls WL in the third direction DR3. The second thickness D2 may be a thickness of the filler member overlapping with the concave portions CNC in the third direction DR3. The first thickness D1 may be thinner than the second thickness D2.

The lenses LS may have a refractive index higher than the refractive index of the low refractive layer LR. The lenses LS may have a shape complementary to the shape of the low refractive layer LR. The lenses LS may have a convex shape complementary to the shape of the concave portions CNC of the low refractive layer LR at one surface facing the low refractive layer LR. The convex shape of the lenses LS may be disposed corresponding to the concave portions CNC of the low refractive layer LR.

As such, the optical distance between the low refractive layer LR formed along the partition walls WL and the optical functional layer OFL is decreased, so that the light extraction efficient from the front surface can be improved. In addition, the shape of the lenses LS formed along the concave portions CNC of the low refractive layer LR is more freely changed, so that light efficiency can be optimized.

The color filter layer CFL may be disposed on the lens array LA. In embodiments, the color filter layer CFL may be separately manufactured to be bonded to the optical functional layer OFL through a filler member. For example, the optical functional layer OFL formed on the first substrate SUB1 and the color filter layer CLF formed on the second substrate SUB2 may be bonded to each other through the color filter. However, before the optical functional layer OFL and the color filter layer CFL are bonded to each other, the second substrate SUB2 may include at least one partition wall WL and the low refractive layer LR with respect to each of the first to third color filters CF1 to CF3.

The color filter layer CFL may include the first to third color filters CF1 to CF3 disposed in the first direction DR1. The first color filter CF1 may be disposed in the first sub-pixel SP1, the second color filter CF2 may be disposed in the second sub-pixel SP2, and the third color filter CF3 may be disposed in the third sub-pixel SP3.

In an example, the first color filter CF1 may overlap with the first light emitting element LD1 in a plan view on the first optical functional pattern CCP1. The second color filter CF2 may overlap with the second light emitting element LD2 on the second optical functional pattern CCP2. The third color filter CF3 may overlap with the third light emitting element LD3 in a plan view on the light scattering pattern LSP.

Colors of the first to third color filters CF1 to CF3 may correspond to colors of lights emitted from the first to third sub-pixels SP1 to SP3, respectively. For example, the first color filter CF1 is a red color filter, and may include a red color filter material (e.g., a pigment, a dye, or the like). The second color filter CF2 is a green color filter, and may include a green color filter material (e.g., a pigment, a dye, or the like). The third color filter CF3 is a blue color filter, and may include a blue color filter material (e.g., a pigment, a dye, or the like).

The color filter layer CFL may include light blocking patterns LBP disposed between the color filters CF. It may be understood that the emission areas (or light emission areas) EMA and the non-emission area NEMA of the first to third sub-pixels SP1 to SP3 are defined by the light blocking patterns LBP. Areas corresponding to the light blocking patterns LBP may correspond to the non-emission area NEMA. Areas not overlapping with the light blocking patterns LBP in a plan view may correspond to the emission areas EMA.

In embodiments, the light blocking patterns LBP may include at least one of various kinds of light blocking materials. In embodiments, each of the light blocking patterns LBP may be provided in the form of a multi-layer overlapping with at least two color filters among the first to third color filters CF1 to CF3 in a plan view. For example, each of the light blocking patterns LBP may be formed as the first to third color filters CF1 to CF3 overlap with each other. In another example, a light blocking pattern between the first and second color filters CF1 and CF2 among the light blocking patterns LBP may be formed as a multi-layer which the first and second color filters CF1 and CF2 overlap, and a light blocking pattern between the second and third color filters CF2 and CF3 among the light blocking patterns LBP may be formed as a multi-layer which the second and third color filters CF2 and CF3 overlap. A light blocking pattern between the first color filter CF1 and a third color filter CF3 of an adjacent pixel may be formed as a multi-layer which the first and third color filters CF1 and CF3 overlap in a plan view. As such, each of the first to third color filters CF1 to CF3 may extend to the non-emission area NEMA to form the light blocking patterns LBP.

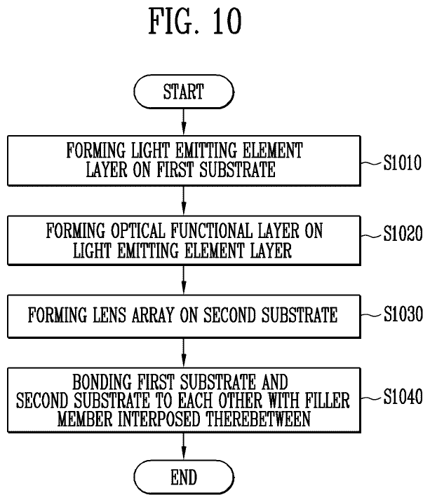

A method of manufacturing the lens array LA will be described later with reference to FIGS. 10 to 15.

FIG. 7 is a sectional view illustrating portion A shown in FIG. 6.

Referring to FIGS. 6 and 7, the partition walls WL may be disposed one surface of the color filter layer CFL, which is opposite to the second substrate SUB2, to be spaced apart from each other in the first direction DR1. Hereinafter, although partition walls WL overlapping with the second color filter CF2 are described, this may be equally applied to partition walls WL overlapping with the first and third color filters CF1 and CF3 in a plan view. In embodiments, the partition walls WL may include external partition walls EWL and internal partition walls IWL. The external partition walls EWL may include a first external partition wall EWL1 disposed between the first color filter CF1 and the second color filter CF2 and a second external partition wall EWL2 disposed between the second color filter CF2 and the third color filter CF3. The internal partition walls IWL may include first and second internal partition walls IWL1 and IWL2 disposed between the first external partition wall EWL1 and the second external partition wall EWL2 to overlap with the second color filter CF2 in a plan view.

The low refractive layer LR may be disposed to cover the first to third color filters CF1 to CF3 and the partition walls WL. The low refractive layer LR may be disposed on the one surface of the color filter layer CFL, which is opposite to the second substrate SUB2, and be in contact with the first to third color filters CF1 to CF3 and the partition walls WL. In some embodiments, the first internal partition wall IWL1 may have a top surface US adjacent to the second color filter CF2, a bottom surface BS opposite to the top surface US, and first and second side surfaces S1 and S2 connecting the top surface US and the bottom surface BS to each other. In addition, the low refractive layer LR may be in contact with the first side surface S1, the second side surface S2, and the bottom surface BS of the first internal partition wall IWL1, and partially surround the first internal partition wall IWL1.

The low refractive layer LR may include concave portions CNC recessed in the third direction DR3 toward a bottom surface of the second color filter CF. The concave portions CNC may be formed between the first external partition wall EWL1 and the first internal partition wall IWL1, between the first internal partition wall IWL1 and the second internal partition wall IWL2, and between the second internal partition wall IWL2 and the second external partition wall EWL2. In FIG. 7, it is illustrated that three concave portions CNC are formed at the bottom surface of the second color filter CF2 to correspond to the second emission area EMA2. However, the present disclosure is not limited thereto. For another example, the low refractive layer LR may include two or more concave portions CNC at the bottom surface of the second color filter CF2.

The thickness of the low refractive layer LR may increase in a direction toward the partition walls WL. The thickness of the low refractive layer LR may increase in a direction toward the partition walls WL from a center CT of each of the concave portions CNC. In other words, a thickness of the low refractive layer LR, which is measured in the opposite direction of the third direction DR3 on the one surface of the color filter layer CFL, may become thicker as becoming closer to the partition walls WL. For example, the low refractive layer LR may have a maximum thickness t1 at portions adjacent to the first and second side surfaces S1 and S2 of the first internal partition wall IWL1.

Meanwhile, the low refractive layer LR may have a minimum thickness t2 at the bottom surface BS of the first internal partition wall IWL1. Thus, the optical distance between the low refractive layer LR and the optical functional layer OFL is decreased through the partition walls WL, thereby improving light efficiency.

FIG. 8 is a plan view illustrating an embodiment of partition walls disposed in the one of the pixels shown in FIG. 3.

Referring to FIG. 8, the first pixel PXL1 may include first to third sub-pixels SP1 to SP3 arranged in the first direction DR1. In addition, the first to third sub-pixels SP1 to SP3 may include first to third color filters CF1 to CF3, respectively.

The first sub-pixel SP1 may include the first color filter CF1 and light blocking patterns LBP at the periphery of the first color filter CF1. The second sub-pixel SP2 may include the second color filter CF2 and light blocking patterns LBP at the periphery of the second color filter CF2. The third sub-pixel SP3 may include the third color filter CF3 and light blocking patterns LBP at the periphery of the third color filter CF3.

The first color filter CF1 may be disposed in an area overlapping with the first emission area EMA1 (see FIG. 6) in which light is emitted in the first sub-pixel SP1. An external partition wall EWL may be disposed along an edge of the first color filter CF1. The external partition walls EWL may overlap the banks BNK in a plan view. In addition, internal partition walls IWL may be disposed to overlap with the first color filter CF1. In some embodiments, two internal partition walls IWL may be disposed in the first color filter CF1. As the two internal partition walls IWL are disposed to be spaced apart from each other in the second direction DR2, three lenses LS (see FIG. 6) arranged in the second direction DR2 may be formed in the first emission area EMA1.

The second color filter CF2 may be disposed in an area overlapping with the second emission area EMA2 (see FIG. 6) in which light is emitted in the second sub-pixel SP2. An external partition wall EWL may be disposed along an edge of the second color filter CF2. In addition, internal partition walls IWL may be disposed to overlap with the second color filter CF2 in a plan view. In some embodiments, one internal partition wall IWL may be disposed in the second color filter CF2. As the one internal partition wall IWL is disposed to extend in the first direction DR1, two lenses LS arranged in the second direction DR2 may be formed in the second emission area EMA2.

The third color filter CF3 may be disposed in an area overlapping with the third emission area EMA3 (see FIG. 6) in which light is emitted in the third sub-pixel SP3 in a plan view. An external partition wall EWL may be disposed along an edge of the third color filter CF3. In some embodiments, any internal partition wall IWL may not be disposed in the third color filter CF3. As any internal partition wall IWL is not disposed, only one lens LS may be formed in the third emission area EMA3.

However, this is merely illustrative, and the present disclosure is not limited thereto. For another example, three or more internal partition walls IWL may be disposed in the first to third color filters CF1 to CF3.

In some embodiments, the internal partition wall IWL may include a material having high transmission characteristics, and the external partition wall EWL may include a light absorbing material. In example, the external partition wall EWL may include a black coloring agent. The black coloring agent may include a black pigment and a black dye. The black coloring agent of the external partition wall EWL may include a metal such as carbon black or chromium, or oxide thereof, but the present disclosure is not limited thereto. The external partition wall EWL includes the light absorbing material, so that reflection caused by external light incident from the outside can be reduced.

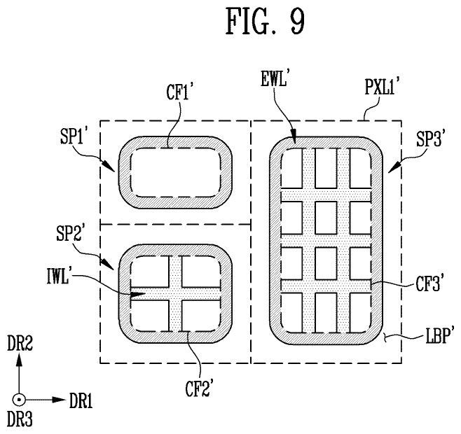

FIG. 9 is a plan view illustrating a pixel in accordance with another embodiment of the present disclosure.

Referring to FIG. 9, a first pixel PXL1′ may include first to third sub-pixels SP1′ to SP3′. In addition, the first to third sub-pixels SP1′ to SP3′ may include first to third color filters CF1′ to CF3′ to correspond thereto, respectively. Hereinafter, descriptions overlapping with those shown in FIG. 8 will be omitted.

The first sub-pixel SP1′ may include the first color filter CF1′ and light blocking patterns LBP′ at the periphery of the first color filter CF1′. The second sub-pixel SP2′ may include the second color filter CF2′ and light blocking patterns LBP′ at the periphery of the second color filter CF2′. The third sub-pixel SP3′ may include the third color filter CF3′ and light blocking patterns LBP′ at the periphery of the third color filter CF3′.

The pixel PXL included in the display panel 110 shown in FIGS. 1 and 3 may include sub-pixels having various arrangements. For example, the display panel 110 may include the first pixel PXL1′ shown in FIG. 8. In the first pixel PXL1′, the first sub-pixel SP1′ and the second sub-pixel SP2′ may be arranged in the second direction DR2. In the first pixel PXL1′, the third sub-pixel SP3′ may be disposed in the first direction DR1 with respect to each of the first and second sub-pixels SP1′ and SP2′. Accordingly, the first color filter CF1′ and the second color filter CF2′ may be arranged in the second direction DR2. The third color filter CF3′ may be disposed in the first direction DR1 with respect to each of the first and second color filters CF1′ and CF2′.

The second sub-pixel SP2′ may have an area larger than an area of the first sub-pixel SP1′, and the third sub-pixel SP3′ may have an area larger than the area of the second sub-pixel SP2′.

Accordingly, the second color filter CF2′ may have an area larger than an area of the first color filter CF1′, and the third color filter CF3′ may have an area larger than the area of the second color filter CF2′. However, embodiments are not limited thereto. For another example, the first and second sub-pixels SP1′ and SP2′ may substantially have the same area, and the third sub-pixel SP3′ may have an area larger than the area of each of the first and second sub-pixels SP1′ and SP2′. As such, the areas of the first to third sub-pixels SP1′ to SP3′ may be variously changed in some embodiments. Accordingly, the areas of the first to third color filters CF1′ to CF3′ may also be variously changed according to the first to third sub-pixels SP1′ to SP3′.

In some embodiments, internal partition walls IWL′ may be disposed in a mesh shape. Two internal partition walls IWL′ may be disposed in the second color filter CF2′. For example, one of the internal partition walls IWL′ may extend in the first direction DR1, and the other of the internal partition walls IWL′ may extend in the second direction DR2. As the two internal partition walls IWL′ are disposed to intersect each other, four lenses LS (see FIG. 6) may be formed in the second emission area EMA2 (see FIG. 6).

Five internal partition walls IWL′ may be disposed in the third color filter CF3′. For example, three of the internal partition walls IWL′ may extend in the first direction DR1, and be disposed to be spaced apart from each other in the second direction DR2. The other two of the internal partition walls IWL′ may extend in the second direction DR2, and be disposed to be spaced apart from each other in the first direction DR1. As the five internal partition walls IWL′ are disposed to intersect each other, twelve lenses LS (see FIG. 6) may be formed in the third emission area EMA3 (see FIG. 6).

As such, lenses LS are formed using at least one partition walls WL with respect to each of the first to third color filters CF1 to CF3, so that the shape of the lenses LS can be freely implemented regardless of sizes of sub-pixels. Thus, the shape of the lenses LS is freely changed in a multi-lens structure, so that light efficiency can be optimized.

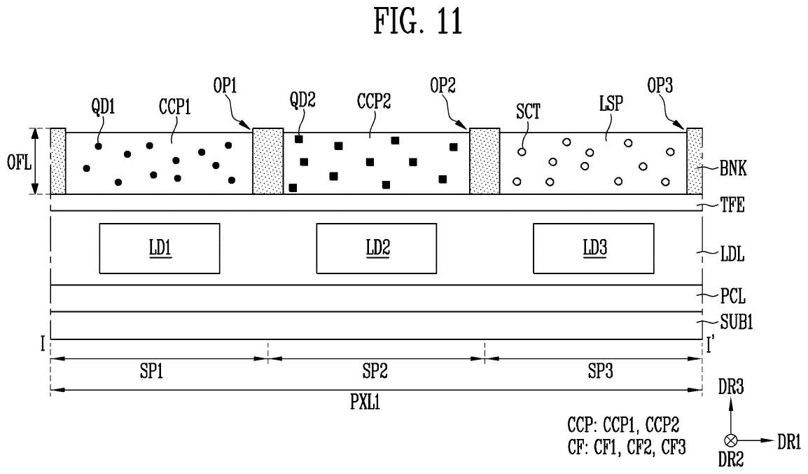

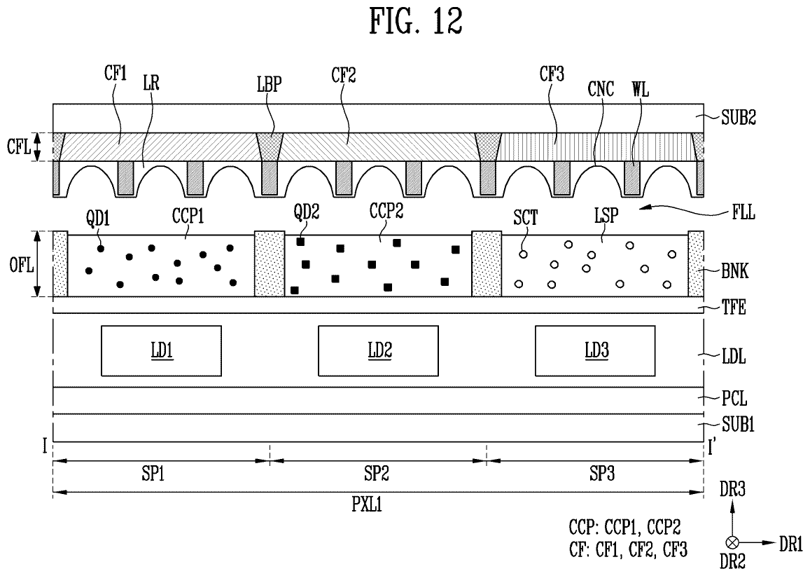

FIG. 10 is a flowchart illustrating an embodiment of a method of manufacturing the display device shown in FIG. 6. FIG. 11 is a sectional view of the display device in S1020 shown in FIG. 10. FIG. 12 is a sectional view of the display device in S1040 shown in FIG. 10. Each of components of the display device 100 may be configured identically to components of the above-described embodiments shown in FIG. 6.

First, referring to FIG. 10, the method of manufacturing the display device 100 in accordance with the embodiment of the present disclosure may include step S1010 of forming a light emitting element layer on a first substrate, step S1020 of forming an optical functional layer on the light emitting element layer, step S1030 of forming a lens array on a second substrate, and step S1040 of bonding the first substrate and the second substrate to each other with a filler member interposed therebetween.

Referring to FIGS. 10 and 11, in S1010, a light emitting element layer LDL including first to third light emitting elements LD1 to LD3 may be formed on a first substrate SUB1. First, a pixel circuit layer PCL may be formed on the first substrate SUB1, and subsequently, the light emitting element layer LDL may be formed on the pixel circuit layer PCL.

The first to third light emitting elements LD1 to LD3 may be formed at positions corresponding to first to third sub-pixels SP1 to SP3, respectively. In embodiments, the first to third light emitting elements LD1 to LD3 may include an organic light emitting diode and/or an inorganic light emitting element. However, the kind of the first to third light emitting elements LD1 to LD3 is not limited thereto.

In addition, a thin film encapsulation layer TFE may be formed on the light emitting element layer LDL. However, the thin film encapsulation layer TFE may be omitted in some embodiments.

Referring to FIGS. 10 and 11, in S1020, an optical functional layer OFL including optical functional patterns and banks BNK disposed between the optical functional patterns may be formed on the light emitting element layer LDL. The optical functional patterns may include first and second optical functional patterns CCP1 and CCP2 and a light scattering pattern LSP.

More specifically, a first opening OP1 corresponding to the first emission area EMA1 (see FIG. 6), a second opening OP2 corresponding to the second emission area EMA2 (see FIG. 6), and a third opening OP3 corresponding to the third emission area EMA3 (see FIG. 6) may be defined on the thin film encapsulation layer TFE by etching the banks BNK.

The first optical functional pattern CCP1 may be formed inside the first opening OP1, and the second optical functional pattern CCP2 may be formed inside the second opening OP2. The light scattering pattern LSP may be formed inside the third opening OP3.

In some embodiments, the first and second optical functional patterns CCP1 and CCP2 and the light scattering pattern LSP may be formed using an inkjet printing technique. In an example, liquid base resin including a first quantum dot QD1 may be provided inside the first opening OP1, and liquid base resin including a second quantum dot QD2 may be provided inside the second opening OP2. The first quantum dot QD1 and the second quantum dot QD2 may include materials having different light emitting wavelengths. Liquid base resin including a scatterer SCT may be provided inside the third opening OP3. After materials corresponding to the first to third openings OP1 to OP3 are provided, the first and second optical functional patterns CCP1 and CCP2 and the light scattering pattern LSP may be formed through curing.

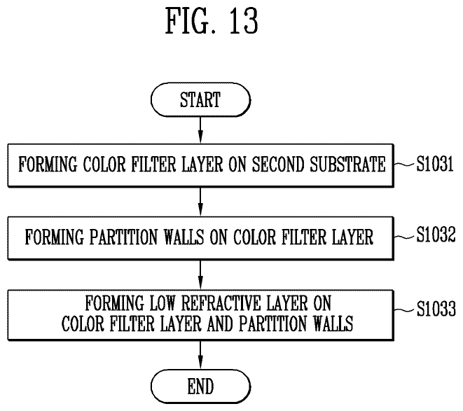

Referring to FIGS. 10 and 12, in S1030, a lens array LA (see FIG. 6) including partition walls WL and a low refractive layer LR covering the partition walls WL may be formed on a second substrate SUB2. However, S1030 will be described later with reference to FIGS. 13 to 15. In addition, in S1040, the first substrate SUB1 and the second substrate SUB2 may be bonded to each other with a filler member FLL interposed therebetween. As the first substrate SUB1 and the second substrate SUB2 are bonded to each other, lenses LS (see FIG. 6) may be formed by the filler member FLL.

More specifically, the second substrate SUB2 on which the partition walls WL and the low refractive layer LR covering the partition walls WL are formed may be disposed such that the top and bottom thereof are reversed. As the second substrate SUB2 is reversed, the low refractive layer LR on the second substrate SUB2 may be disposed to face the optical functional layer OFL on the first substrate SUB1. In addition, the filler member FLL may be provided, which fills a separation space between the first substrate SUB1 and the second substrate SUB2. The filler member FLL may be filled in concave portions CNC between the partition walls WL within the separation space between the first substrate SUB1 and the second substrate SUB2. That is, the filler member FLL may have a refractive index higher than a refractive index of the low refractive layer LR, and be filled in a convex shape, corresponding to the concave portions CNC. Accordingly, at least two lenses LS having a convex shape may be formed in each of the first and second optical functional patterns CCP1 and CCP2 and the light scattering pattern LSP.

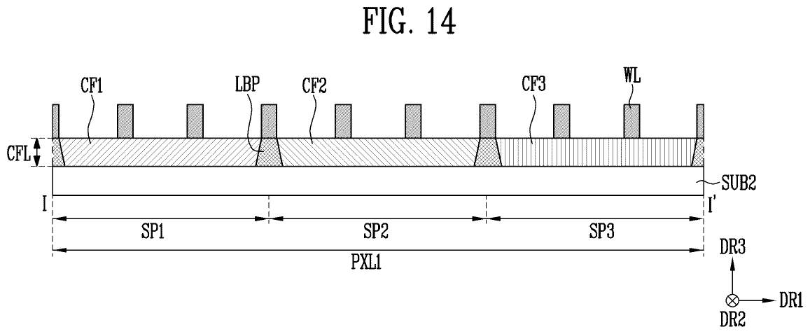

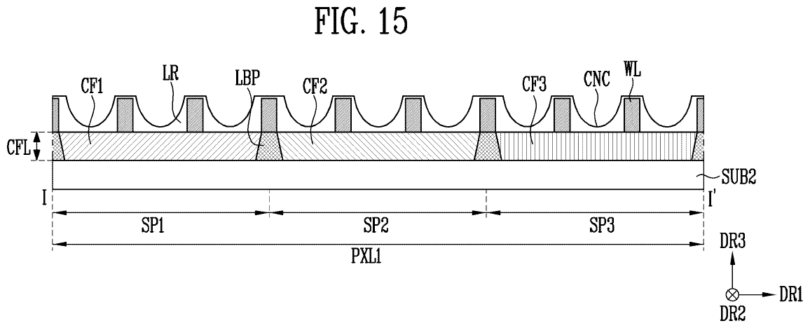

FIG. 13 is a flow chart illustrating an embodiment of S1030 shown in FIG. 10. FIG. 14 is a sectional view of the display device in S1032 shown in FIG. 13. FIG. 15 is a sectional view of the display device in S1033 shown in FIG. 13.

First, referring to FIG. 13, the step S1030 of forming the lens array on the second substrate, which is shown in FIG. 10, may include step S1031 of forming a color filter layer on the second substrate, step S1032 of forming partition walls on the color filter layer, and step S1033 of forming a low refractive layer on the color filter layer and the partition walls.

Referring to FIGS. 13 and 14, in S1031, a color filter layer CFL including first to third color filters CF1 to CF3 and light blocking patterns LBP may be formed on the second substrate SUB2. The first to third color filters CF1 to CF3 may be disposed to overlap with the first to third sub-pixels SP1 to SP3 in a plan view, respectively.

In S1032, partition walls WL disposed to be spaced apart from each other in the first direction DR1 may be formed on the color filter layer CFL. The partition walls WL may be disposed to overlap with a boundary between the first sub-pixel SP1 and the second sub-pixel SP2 and a boundary between the second sub-pixel SP2 and the third sub-pixel SP3 in a plan view. The partition walls WL may be disposed to surround each of the first to third sub-pixels SP1 to SP3. In addition, at least one partition wall WL may be disposed to overlap with each of the first to third sub-pixels SP1 to SP3.

Referring to FIGS. 13 and 15, in S1033, a low refractive layer LR covering the partition walls WL and one surface of the color filter layer CFL, on which the partition walls WL are disposed, may be formed on the second substrate SUB2.

More specifically, a material having a refractive index of 1 to 1.5 may be applied on the entirety of the second substrate SUB2. Accordingly, the low refractive layer LR may be formed over the partition walls WL and the one surface of the color filter layer CFL between the partition walls WL.

In embodiments, the low refractive layer LR may partially surround the partition walls WL, and be partially in contact with the first to third color filters CF1 to CF3. As the partition walls WL are disposed to be spaced apart from each other, the low refractive layer LR may include concave portions CNC recessed toward a bottom surface of the color filter layer CFL. The thickness of the low refractive layer LR may increase in a direction toward the partition walls WL from a center of each of the concave portions CNC. Also, the low refractive layer LR may have a minimum thickness at one surface of each of the partition walls WL, which is opposite to the color filter layer CFL.

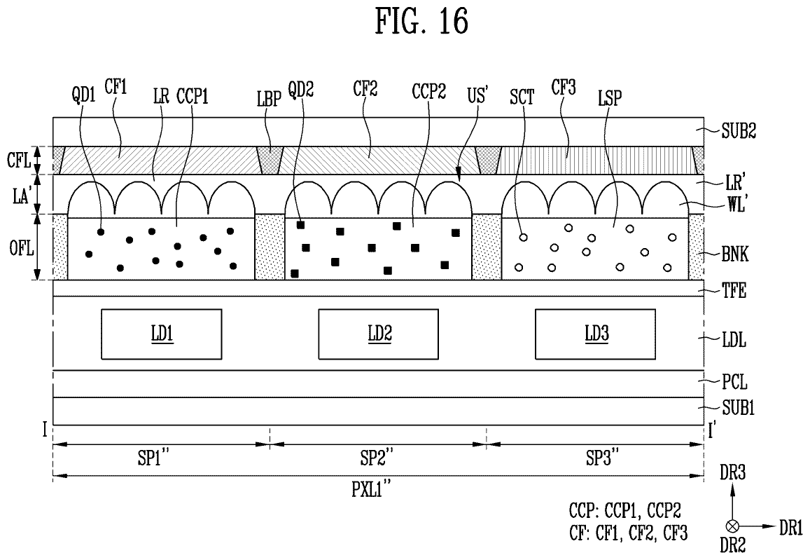

FIG. 16 is a sectional view illustrating another embodiment of the display device.

Referring to FIG. 16, there may be provided a first substrate SUB1, a pixel circuit layer PCL, a first light emitting element LD1 of a first sub-pixel SP1″, a second light emitting element LD2 of a second sub-pixel SP2″, a third light emitting element LD3 of a third sub-pixel SP3″, a light emitting element layer LDL, a thin film encapsulation layer TFE, an optical functional layer OFL, first to third color filters CF1 to CF3, light blocking patterns LBP, a color filter layer CFL, and a second substrate SUB2.

The first substrate SUB1, the pixel circuit layer PCL, the first light emitting element LD1, the second light emitting element LD2, the third light emitting element LD3, the light emitting element layer LDL, the thin film encapsulation layer TFE, the optical functional layer OFL, the first to third color filters CF1 to CF3, the light blocking patterns LBP, the color filter layer CFL, and the second substrate SUB2 may be described like the embodiments shown in FIG. 6. In relation to the embodiments shown in FIG. 6, overlapping descriptions will be omitted, and portions different from those of the above-described embodiments will be mainly described.

In a lens array LA′, partition walls WL′ having a lens shape may be disposed on the optical functional layer OFL. The partition walls WL′ may include the same material as the partition walls WL shown in FIG. 6. The partition walls WL′ may have a light transmittance of 95% or more. Also, the partition walls WL′ may be formed in the form of at least one of an engraved pattern and an embossed pattern. In FIG. 16, it is illustrated that the partition walls WL′ are embossed patterns. However, the present disclosure is not limited thereto. For another example, the partition walls WL′ may be engraved patterns.

At least two partition walls WL′ may be disposed to overlap with first and second optical functional patterns CCP1 and CCP2 and a light scattering pattern LSP along the first direction DR1. The partition walls WL′ may have a convex shape with the same height in the third direction DR3 perpendicular to the first direction DR1. In FIG. 16, it is illustrated that numbers of partition walls WL′ disposed in the first to third sub-pixels SP1″ to SP3″ are the same. However, the present disclosure is not limited thereto. For another example, the first sub-pixel SP1″ may have four partition walls WL′. In addition, each of the second and third sub-pixels SP2″ and SP3″ may include partition walls WL of which number is smaller than or greater than the four partition walls WL4.

A low refractive layer LR′ may be disposed over the partition walls WL′. In some embodiments, the low refractive layer LR′ may have a property that a low temperature process of 100 degrees or lower is possible. Accordingly, the low refractive layer LR′ may form lenses directly on the optical functional layer OFL through the low temperature process.

A bottom surface of the low refractive layer LR′, which is adjacent to the optical functional layer OFL, may be in contact with a top surface US' of the partition walls WL′. Accordingly, the top surface of the low refractive layer LR′ may have concave shapes complementary to convex shapes of the partition walls WL′. On the other hand, a top surface of the low refractive layer LR′, which is adjacent to the color filter layer CFL, may be a flat surface.

In the display device and the method of manufacturing the same in accordance with the embodiments of the present disclosure, a multi-lens structure is formed using at least one partition wall WL and the low refractive layer LR with respect to each of the first to third color filters CF1 to CF3, so that the optical distance between the low refractive layer LR and the optical functional layer OFL can be decreased, thereby improving light efficiency. In addition, the shape of the lenses LS can be freely implemented through the partition walls WL regardless of sizes of sub-pixels, so that light efficiency can be optimized by changing the shape of the lenses LS.

In accordance with the present disclosure, there can be provided a display device having improved light efficiency and a method of manufacturing the display device.

Embodiments provide a display device having improved light efficiency. For example, in the display device, lenses are formed using partition walls and a low refractive layer, so that the light efficiency can be improved by increasing light emitted in a front direction.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a light emitting element layer;
an optical functional layer including optical functional patterns arranged on the light emitting element layer and a bank disposed between the optical functional patterns;
a color filter layer disposed on the optical functional layer, the color filter layer including color filters overlapping the optical functional patterns in a plan view; and
a lens array disposed between the optical functional layer and the color filter layer,
wherein the lens array includes:
partition walls arranged on a bottom surface of the color filter layer, which are adjacent to the optical functional layer; and
a low refractive layer covering the partition walls and the bottom surface of the color filter layer.

2. The display device of claim 1, wherein the partition walls have a refractive index higher than a refractive index of the low refractive layer.

3. The display device of claim 1, wherein the partition walls have a light transmittance of 95% or more.

4. The display device of claim 1, wherein the low refractive layer has a refractive index of 1 to 1.5.

5. The display device of claim 1, wherein each of the optical functional patterns overlaps with at least one of the partition walls in the plan view.

6. The display device of claim 1, wherein a bottom surface of the low refractive layer, which is adjacent to the optical functional layer, includes concave portions recessed toward the bottom surface of the color filter layer.

7. The display device of claim 6, wherein each of the optical functional patterns overlaps with at least two of the concave portions in the plan view.

8. The display device of claim 1, wherein the lens array further includes lenses disposed between the optical functional layer and the low refractive layer.

9. The display device of claim 8, wherein each of the lenses has a refractive index higher than the refractive index of the low refractive layer.

10. The display device of claim 8, wherein each of the lenses has a shape complementary to a shape of a portion of the low refractive layer facing the lens.

11. The display device of claim 8, wherein each of the lenses has a first thickness at the partition walls and has a second thickness at the bottom surface of the color filter layer between the partition walls, and
wherein the first thickness is thinner than the second thickness.

12. The display device of claim 1, wherein the color filters include a first color filter and a second color filter, which are arranged in a certain direction, and
wherein the partition walls include:
an external partition wall overlapping the bank; and
at least one internal partition wall overlapping with each of the first and second color filters in the plan view.

13. The display device of claim 12, wherein the external partition wall is disposed along an edge of each of the first and second color filters in the plan view.

14. The display device of claim 12, wherein the external partition wall includes a light absorbing material.

15. The display device of claim 1, wherein a thickness of the low refractive layer increases in a direction toward the partition walls.

16. The display device of claim 1, wherein one of the partition walls has a top surface adjacent to the color filter layer, a bottom surface opposite to the top surface, and first and second side surfaces connecting the top surface and the bottom surface to each other, and
wherein the low refractive layer is in contact with the first side surface, the second side surface, and the bottom surface, and surrounds part of the partition walls.

17. A display device comprising:
a light emitting element layer;
an optical functional layer including optical functional patterns arranged on the light emitting element layer and a bank disposed between the optical functional patterns;
a color filter layer disposed on the optical functional layer, the color filter layer including color filters overlapping with the optical functional patterns in a plan view; and
a lens array disposed between the optical functional layer and the color filter layer,
wherein the lens array includes:
lenses disposed on the optical functional layer, the lenses having at least two convex shapes overlapping with each of the optical functional patterns in the plan view; and
a low refractive layer covering the lenses and a bottom surface of the color filter layer, which is adjacent to the optical functional layer.

18. The display device of claim 17, wherein the low refractive layer has a property that a low temperature process of 100 degrees or lower is possible.

19. A method of manufacturing a display device, the method comprising:
forming a light emitting element layer on a first substrate;
forming, on the light emitting element layer, an optical functional layer including optical functional patterns and a bank disposed between the optical functional patterns;
forming, on a second substrate, a color filter layer including color filters overlapping with the optical functional patterns;
forming partition walls on the color filter layer;
forming a low refractive layer covering the partition walls and the color filter layer; and
bonding the first substrate and the second substrate to each other with a filler member interposed therebetween.
